(19) United States
(12) Patent Application Publication
(10) Pub. No.: US 2008/0157233 A1
(43) Pub. Date: Jul. 3, 2008

(54) Method for fabricating a semiconductor device

(75) Inventor: Hyuk Park, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 11/987,863

(22) Filed: Dec. 5, 2007

(30) Foreign Application Priority Data
Dec. 28, 2006 (KR) 10-2006-0135919

(51) Int. Cl. H01L 29/78; H01L 21/336

(52) U.S. Cl. 257/412; 438/303; 257/E21.409; 257/E29.255

(57) ABSTRACT

A method for fabricating a semiconductor device is provided. A gate pattern including a gate insulation layer, an oxidation suppression layer, and a polysilicon layer is formed over a substrate. A first metal layer is formed over the substrate, and first and second silicide layers are formed over the polysilicon layer and the impurity regions by performing a first thermal annealing process. A non-reacted portion of the first metal layer is removed. A premetal dielectric (PMD) layer is formed over the substrate, and polished to expose the first silicide layer. A second metal layer is formed over the PMD layer. A second thermal annealing process is performed to the second metal layer to fully silicide the polysilicon layer and the oxidation suppression layer, thereby forming a third silicide layer. A non-reacted portion of the second metal layer is removed.

### RELATED APPLICATIONS

This application claims the benefit of priority to Korean Patent Application No. 10-2006-0135919, filed on Dec. 28, 2006, the entire contents of which are incorporated herein by reference.

### BACKGROUND

1. Technical Field

Embodiments consistent with the present invention relate to a method for fabricating a semiconductor device, and more particularly, to a method for fabricating a semiconductor device including a fully silicided gate.

2. Related Art

As the size of a unit semiconductor device decreases due to the high integration of semiconductor devices, a gate oxide layer of the unit semiconductor device may need to be formed to have a thickness of about 2 nm or less. However, as the thickness of the gate oxide layer decreases, a gate depletion effect is more likely to occur. As a result, the performance of the semiconductor devices tends to be degraded. Also, the gate depletion effect may decrease an equivalent oxide thickness (ETO) of the gate oxide layer, which may affect impurity penetration, particularly boron penetration in the semiconductor devices.

As the size of the unit semiconductor device decreases, reducing a thermal budget may be important for forming an ultra shallow junction.

Currently, a fully silicided (FUSI) gate is suggested in an effort to obviate the above described conditions.

A FUSI gate may reduce the resistance of the gate and may prevent boron ions from penetrating into a channel. Also, the FUSI gate may be compatible with a gate formed of a high-K dielectric material.

FIGS. 1A through 1D are sectional views illustrating a conventional method for fabricating a semiconductor device.

Referring to FIG. 1A, a device isolation structure 13 is formed in a substrate 11 by performing a shallow trench isolation (STI) process. Device isolation structure 13 may define an active region of substrate 11. A gate insulation layer and a polysilicon layer may be formed on substrate 11, and patterned through a photolithography process to form a gate pattern, including a patterned gate insulation layer 15 and a patterned polysilicon layer 17, in the active region.

Impurity ions having a conductivity type opposite to that of substrate 11 may be doped with a low concentration using patterned polysilicon layer 17 as a mask to form lightly doped drain (LDD) regions 19.

A spacer 21 is formed on both sidewalls of the polysilicon layer 17. Impurity ions having a conductivity type opposite to that of substrate 11 is doped with high concentration using the gate pattern and spacer 21 as a mask, so as to form impurity regions 23, a portion of which overlaps with LDD regions 19. Impurity regions 23 may be used as source and drain regions.

Referring to FIG. 1B, a first metal layer (not shown) may be deposited over substrate 11 to cover patterned polysilicon layer 17. The first metal layer may comprise a conductive metal, such as titanium (Ti), cobalt (Co), or molybdenum (Mo). A first thermal annealing process may be performed on the first metal layer to form first and second silicide layers 25 and 27 respectively on patterned polysilicon layer 17 and impurity regions 23.

The first thermal annealing process may include two steps. In a first step, a silicidation reaction process may take place between the first metal layer and the surfaces of patterned polysilicon layer 17 and impurity regions 23. As a result, first and second silicide layers 25 and 27 are formed. At this time, the silicidation reaction process may not have taken place on device isolation structure 13 and/or spacer 21. Also, a remaining portion of the first metal layer not subjected to the silicidation reaction process may be removed, and a second step may proceed thereafter. The second step may be performed to stabilize first and second silicide layers 25 and 27 formed in the first step, so as to decrease the resistance of first and second silicide layers 25 and 27.

Referring to FIG. 1C, a liner layer 29 is formed over substrate 11, such that liner layer 29 covers device isolation structure 13, spacer 21, and first and second silicide layers 25 and 27. Liner layer 29 may comprise silicon nitride. A silicon oxide layer may be formed over liner layer 29 to form a premetal dielectric (PMD) layer 31.

PMD layer 31 and liner layer 29 may be chemically and mechanically polished to expose first silicide layer 25. A second metal layer 33 is formed on PMD layer 31 to contact first silicide layer 25. Second metal layer 33 may comprise a conductive metal such as Ti, Co, or Mo.

Referring to FIG. 1D, a second thermal annealing process may be performed to fully silicide patterned polysilicon layer 17. As a result of the full silicidation of patterned polysilicon layer 17, a third silicide layer 35 is formed. Third silicide layer 35 may be used as a gate.

The second thermal annealing process may include two steps. In a first step, second metal layer 33 may undergo a silicidation reaction process with first silicide layer 25, but not with PMD layer 31 and liner layer 29 that contact second metal layer 33. A remaining portion of second metal layer 33, in which the silicidation reaction process has not taken place, may be removed, and a second step may proceed thereafter. The second step allows metal elements of second metal layer 33 from the silicidation reaction process to diffuse into the entire region of patterned polysilicon layer 17 above patterned gate insulation layer 15, so as to complete the silicidation reaction process. In other words, patterned polysilicon layer 17 of the gate pattern may be fully silicided.

However, in the conventional method, a native oxide layer remaining on substrate 11 may impede the silicidation of patterned polysilicon layer 17, which is achieved by diffusing the metal elements into the entire region of patterned polysilicon layer 17. As a result, adhesion between patterned polysilicon layer 17 and patterned gate insulating layer 15 may be decreased. Further, an electrical property of the semiconductor devices, such as resistance, may not be consistent throughout.

### SUMMARY

In light of the above, embodiments consistent with the present invention provide a method for fabricating a semiconductor device including a fully silicided gate pattern.

In one embodiment consistent with the present invention, there is provided a method for fabricating a semiconductor device. The method includes forming a gate pattern over a substrate, the gate pattern including a gate insulation layer, an oxidation suppression layer, and a polysilicon layer, forming a spacer on sidewalls of the gate pattern, forming impurity regions on the substrate at both sides of the gate pattern, the impurity regions having a conductivity type opposite to that of the substrate, forming a first metal layer over the substrate, forming first and second silicide layers over the polysilicon layer and the impurity regions by performing a first thermal annealing process, removing a non-reacted portion of the first metal layer, forming a premetal dielectric layer over the substrate to cover a device isolation structure of the substrate, the spacer, and the first and second silicide layers, polishing the premetal dielectric layer to expose the first silicide layer, forming a second metal layer over the premetal dielectric layer to contact the first silicide layer, the second metal layer comprising a conductive metal substantially the same as the first metal layer comprises, performing a second thermal annealing process to the second metal layer to fully silicide the polysilicon layer and the oxidation suppression layer, thereby forming a third silicide layer, and removing a non-reacted portion of the second metal layer.

### BRIEF DESCRIPTION OF THE DRAWINGS

The above and other features consistent with the present invention will become apparent from the following detailed description with reference to the accompanying drawings, in which:

FIGS. 1A through 1D are sectional views illustrating a conventional method for fabricating a semiconductor device; and

FIGS. 2A through 2D are sectional views illustrating a method for fabricating a semiconductor device in accordance with an embodiment consistent with the present invention.

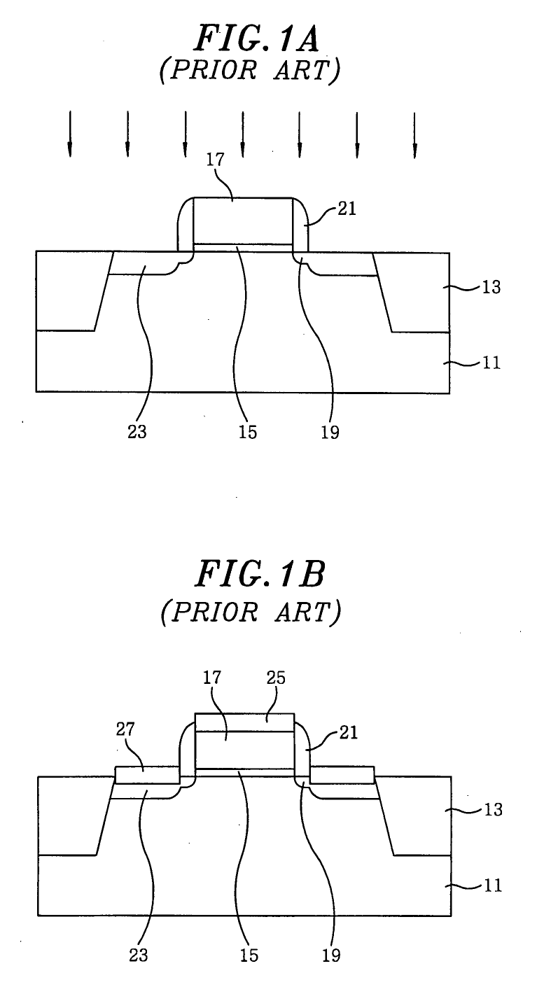

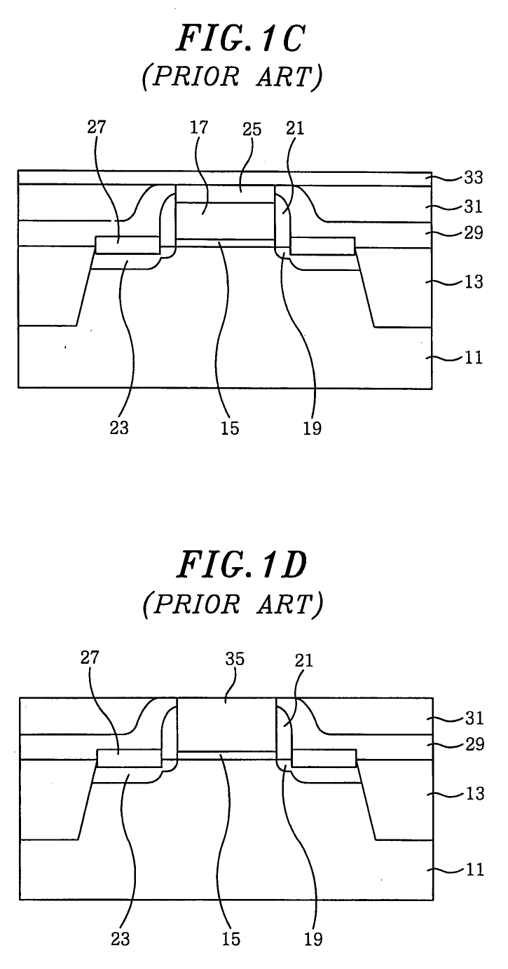

### DETAILED DESCRIPTION

Hereinafter, embodiments consistent with the present invention will be described in detail with reference to the accompanying drawings, so that they can be readily implemented by those skilled in the art.

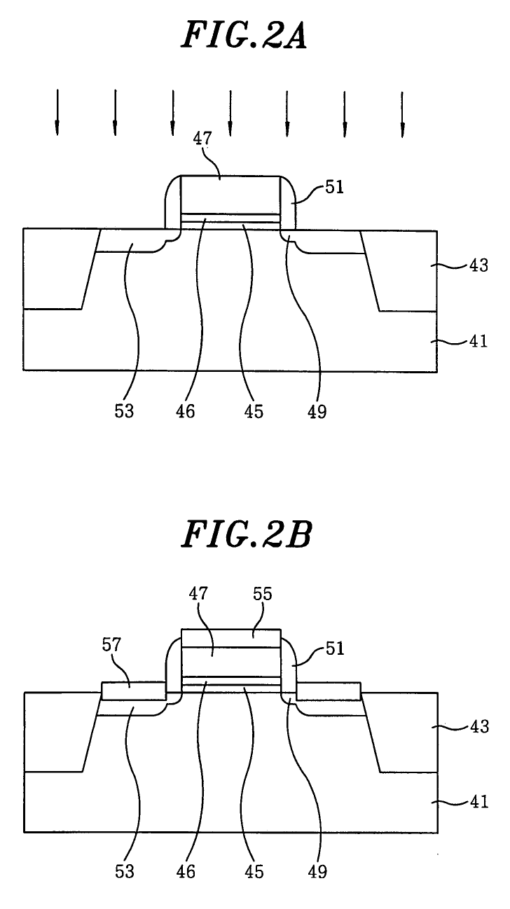

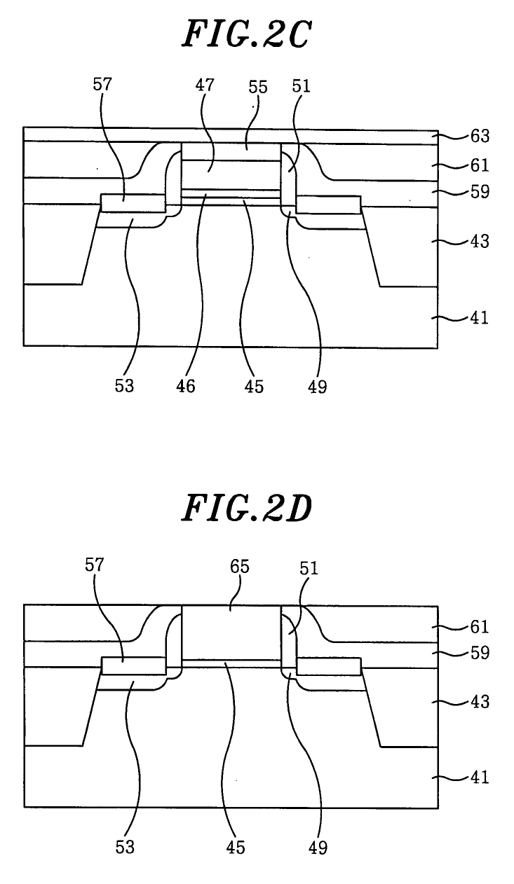

FIGS. 2A through 2D are sectional views illustrating a method for fabricating a semiconductor device in accordance with an embodiment consistent with the present invention.

Referring to FIG. 2A, a device isolation structure 43 is formed in a substrate 41 by performing a shallow trench isolation (STI) process. Device isolation structure 43 may define an active region of substrate 41.

A gate insulation layer 45, which may comprise silicon nitric oxide (SiNO), is formed over the active region of substrate 41 to have a thickness ranging from about 20 Å to about 25 Å. An oxidation suppression layer 46 is formed over gate insulation layer 45. Oxidation suppression layer 46 may comprise an amorphous silicon-based layer having a thickness of about 120 Å to about 200 Å and may be formed by performing a radio frequency (RF) sputtering method at a chamber pressure of about 1×10⁻⁷ Torr to about 4×10⁻⁷ Torr. Oxidation suppression layer 46 may suppress the growth of a native oxide layer (not shown) existing over substrate 41 during subsequent thermal annealing processes.

A polysilicon layer 47 is formed over oxidation suppression layer 46 by performing a chemical vapor deposition (CVD) method. In one embodiment, polysilicon layer 47 may have a thickness ranging from about 1,000 Å to about 2,000 Å.

Polysilicon layer 47, oxidation suppression layer 46, and gate insulation layer 45 are sequentially patterned through a photolithography process to form a gate pattern.

Impurity ions having a conductivity type opposite to that of substrate 41 is doped at a low concentration using patterned polysilicon layer 47 as a mask to form lightly doped drain (LDD) regions 49.

A spacer 51 is formed on sidewalls of oxidation suppression layer 46 and patterned polysilicon layer 47. Impurity ions having a conductivity type opposite to that of substrate 41 may be doped with high concentration in substrate 41 using patterned polysilicon layer 47 and spacer 51 as a mask, so as to form impurity regions 53, a portion of which overlaps with LDD regions 49. Impurity regions 53 may be used as source and drain regions.

Referring to FIG. 2B, although not illustrated, a first metal layer may be formed over substrate 41 to cover patterned polysilicon layer 47 by performing a CVD method. The first metal layer may comprise a conductive metal, such as titanium (Ti), cobalt (Co), or molybdenum (Mo). A first thermal annealing process may be performed to the first metal layer to form first and second silicide layers 55 and 57 respectively over patterned polysilicon layer 47 and impurity regions 53.

The first thermal annealing process may comprise two steps. In a first step, a silicidation reaction process may take place between the first metal layer (not shown) and surfaces of patterned polysilicon layer 47 and impurity regions 53. As a result, first and second silicide layers 55 and 57 are formed. In one embodiment, the silicidation reaction process may not have occurred over device isolation structure 43 and spacer 51.

A remaining portion of the first metal layer (not shown) that does not participate in the silicidation reaction process may be removed, and a second step may proceed thereafter. The second step may be performed to stabilize first and second silicide layers 55 and 57 so as to reduce resistance of first and second silicide layers 55 and 57.

Referring to FIG. 2C, a liner layer 59 is formed over substrate 41 to cover device isolation structure 43, spacer 41, and first and second silicide layers 55 and 57. Liner layer 59 may comprise a silicon nitride-based material, and may be formed to have a thickness ranging from about 1,000 Å to about 1,500 Å by performing a CVD method. A premetal dielectric (PMD) layer 61 is formed to have a thickness of about 4,500 Å to about 6,000 Å over liner layer 59 by performing a CVD method. PMD layer 61 may comprise a silicon oxide-based material, such as borophosphosilicate glass (BPSG), undoped silicate glass (USG), or tetraethyl orthosilicate (TEOS). Liner layer 59 may reduce stress produced between spacer 51 and PMD layer 61.

PMD layer 61 and liner layer 59 may be polished by performing a CMP process to expose first silicide layer 55. A second metal layer 63 is formed on PMD layer 61 to have a thickness of about 500 Å to about 700 Å by performing a physical vapor deposition (PVD) method. Second metal layer 63 is formed to contact first silicide layer 55. In one embodiment, second metal layer 63 may include a conductive metal substantially the same as the first metal layer, that is, Ti, Co, or Mo.

Referring to FIG. 2D, a second thermal annealing process may be performed to fully silicide polysilicon layer 47 and oxidation suppression layer 46, so as to form a third silicide layer 65. Third silicide layer 65 may be used as a gate.

The second thermal annealing process may comprise two steps. In a first step, a rapid thermal annealing (RTA) process may be performed by sequentially applying temperatures of about 450° C., 485° C., and 350° C. to the semiconductor device. In one embodiment, second metal layer 63 may undergo a silicidation reaction process with first silicide layer 55, but not with PMD layer 61 and liner layer 59.

A remaining portion of second metal layer 63, on which has not undergone the silicidation reaction process, may be removed, and a second step may be performed thereafter. The remaining portion of second metal layer 63 may be removed using a mixture solution of sulfuric acid (H₂SO₄) and deionized water, and a mixture solution of tetramethyl ammonium hydroxide (TMH) and deionized water.

The second step of the second thermal annealing process allows metal elements of first silicide layer 55 to diffuse into patterned polysilicon layer 47 and oxidation suppression layer 46, so as to perform a silicidation reaction process. The second step may proceed by sequentially applying temperatures of about 450° C., 600° C., and 400° C. to the semiconductor device. As a result, oxidation suppression layer 46 and patterned polysilicon layer 47 may be fully silicided.

Oxidation suppression layer 46 may suppress a native oxide layer remaining on substrate 41 and may prevent the native oxide layer from becoming a part of patterned polysilicon layer 47. Thus, patterned polysilicon layer 47 may not be oxidized and may be fully silicided. As a result, adhesion between patterned polysilicon layer 47 and gate insulation layer 45 may not decrease, and a consistent electrical property of the semiconductor device may be achieved.

As described above, oxidation suppression layer 46, which may comprise an amorphous silicon-based material, may be formed between gate insulation layer 45 and patterned polysilicon layer 47. Thus, when patterned polysilicon layer 47 is fully silicided, oxidation suppression layer 46 may suppress the native oxide layer from growing into a part of patterned polysilicon layer 47.

While embodiments consistent with the present invention have been described, it is to be understood by those skilled in the art that various changes and modifications may be made without departing from the spirit and scope of the present invention as defined in the following claims.

What is claimed is:

1. A method for fabricating a semiconductor device, the method comprising:
forming a gate pattern over a substrate, the gate pattern including a gate insulation layer, an oxidation suppression layer, and a polysilicon layer;
forming a spacer on sidewalls of the gate pattern;
forming impurity regions on the substrate at both sides of the gate pattern, the impurity regions having a conductivity type opposite to that of the substrate;
forming a first metal layer over the substrate;
forming first and second silicide layers over the polysilicon layer and the impurity regions by performing a first thermal annealing process;
removing a non-reacted portion of the first metal layer;
forming a premetal dielectric layer over the substrate to cover a device isolation structure of the substrate, the spacer, and the first and second silicide layers;
polishing the premetal dielectric layer to expose the first silicide layer;
forming a second metal layer over the premetal dielectric layer to contact the first silicide layer, the second metal layer comprising a conductive metal substantially the same as the first metal layer comprises;
performing a second thermal annealing process to the second metal layer to fully silicide the polysilicon layer and the oxidation suppression layer, thereby forming a third silicide layer; and
removing a non-reacted portion of the second metal layer.

2. The method of claim 1, wherein forming the gate pattern over the substrate comprises forming the oxidation suppression layer to have a thickness ranging from about 120 Å to about 200 Å, the oxidation suppression layer comprising an amorphous silicon-based material.

3. The method of claim 2, wherein forming the oxidation suppression layer comprises performing a radio frequency sputtering method.

4. The method of claim 1, wherein the second metal layer comprises one selected from the group consisting of titanium (Ti), cobalt (Co), and molybdenum (Mo).

5. The method of claim 4, wherein forming the second metal layer comprises performing a physical vapor deposition method and forming the second metal layer to have a thickness ranging from about 500 Å to about 700 Å.

6. The method of claim 1, wherein the second thermal annealing process comprises:
a first step of performing a silicidation reaction process between the second metal layer and the first silicide layer; and
a second step of removing the non-reacted portion of the second metal layer and diffusing metal elements of the first silicide layer into the polysilicon layer and the oxidation suppression layer.

7. The method of claim 6, wherein the first step comprises performing a rapid thermal annealing process by sequentially applying temperatures of about 450° C., 485° C., and 350° C. to the semiconductor device.

8. The method of claim 6, wherein the second step comprises performing a rapid thermal annealing process by sequentially applying temperatures of about 450° C., 600° C., and 400° C. to the semiconductor device.

9. A semiconductor device, comprising:
a gate pattern formed over a substrate, the gate pattern including a gate insulation layer and a fully silicided polysilicon layer;
a spacer formed on sidewalls of the gate pattern;
impurity regions formed on the substrate at both sides of the gate pattern, the impurity regions having a conductivity type opposite to that of the substrate;
a first metal layer formed over the substrate;
a first and a second silicide layers formed over the impurity regions;
a premetal dielectric layer formed over the substrate to cover a device isolation structure of the substrate, the spacer, and the first and second silicide layers;
a second metal layer formed over the premetal dielectric layer contacting the first silicide layer, the second metal layer including a conductive metal substantially the same as the first metal layer.
